(19) United States
(12) Patent Application Publication
(10) Pub. No.: US 2007/0105050 A1
(43) Pub. Date: May 10, 2007

(54) Method and apparatus for producing microchips

(75) Inventors: Shahab Jahromi, Maastricht (NL); Wienke Dietrich, Elsloo (NL); Leonardus Bremer, Vise (BE)

Correspondence Address: NIXON & VANDERHYE, PC, 901 NORTH GLEBE ROAD, 11TH FLOOR, ARLINGTON, VA, 22203, US

(73) Assignee: DSM IP ASSETS B.V., Te Heerlem (NL)

(21) Appl. No.: 10/578,265

(22) PCT Filed: Oct. 28, 2004
(86) PCT No.: PCT/EP04/12248

§ 371 Date: Jul. 3, 2006

Related U.S. Application Data
(60) Provisional application No. 60/551,629, filed on Mar. 10, 2004.

(30) Foreign Application Priority Data
Nov. 5, 2003 (EP) 03078487.0
Mar. 10, 2004 (EP) 04075712.2
Mar. 31, 2004 (EP) 04075984.7
Jul. 23, 2004 (EP) 04077144.6

(51) Int. Cl. G03F 7/20

(52) U.S. Cl. 430/311

(57) ABSTRACT

Method for producing microchips by using immersion lithography, wherein the immersion fluid comprises an additive so that the refractive index of the immersion fluid is increased relative to the fluid not comprising the additive. The exposure light in the method has improved resolution, so that microchips having an increased integration density are obtained. The invention also relates to the immersion fluid and an apparatus for immersion lithography, comprising the immersion fluid.

The invention relates to a method as well as an apparatus for producing microchips by using immersion lithography.

Since the invention of integrated circuits in 1959, the computing power of microprocessors has been doubled every 18 months and every three years a new generation of microchips has been introduced, every time reducing the size of electronic devices. This phenomenon is known as Moore's law. The performance of the microchip is, to a large degree, governed by the size of the individual circuit elements, such as for example cupper and aluminium lines, in the microchip. A microchip in general comprises a complex three-dimensional structure of alternating, patterned layers of conductors, dielectrics, and semiconductor films. As a general rule, the smaller the circuit elements, the faster the microchip and the more operations it can perform per unit of time. This phenomenal rate of increase in the integration density of the microchips has been sustained in large by advances in optical lithography, which has been the method of choice for producing the microchips.

A higher degree of integration of the circuit requires a shorter wavelength of exposure light used in the method of producing microchips by optical lithography. Changing the exposure light to shorter wavelengths has indeed been the method of choice to increase the resolution. However, switching to shorter wavelengths is becoming increasingly a daunting task as new exposure tools and materials such as photo-resists must be designed. This is a difficult task and it often results in implementation issues and delays. Therefore chip manufacturers generally tend to postpone the introduction of a new exposure wavelength as long as possible and attempt to prolong the lifetime of an existing technology using alternative approaches. Already for a period of time immersion lithography is considered to be an effective method to improve the resolution limit of a given exposure wavelength. Here the air between the bottom lens of the apparatus for producing the microchips and the silicon wafer having a layer of photoresist on top, is replaced with an immersion fluid, leading essentially to a decrease in effective wave length, see for example: A. Takanashi et al. U.S. Pat. No. 4,480,910 (1984). Preferably the fluid has a high transparency at least at the wavelength of the exposure light, does not influence the chemistry of the photoresist on top of the silicon wafer used to produce the microchip and does not degrade the surface of the lens.

Immersion lithography is for example possible for the wavelengths 248 nm, 193 nm and 157 nm. Because of its transparency at 193 nm water is the main candidate for immersion fluid at this wavelength. (See for example: J. H. Burnett, S. Kaplan, Proceedings of SPIE, Vol. 5040, P. 1742 (2003). Because of exceptional transparency of fluorinated and siloxane-based compounds at 157 nm, such fluids are being considered for 157 nm immersion lithography.

Aim of the invention is to provide a method for producing microchips by using immersion lithography showing further resolution enhancement.

Surprisingly this aim is achieved because the immersion fluid comprises an additive so that the refractive index of the immersion fluid is higher than the refractive index of the fluid not comprising the additive.

Preferably the refractive index of the immersion fluid is at least 1% higher, more preferably at least 2% higher, still more preferably at least 5% higher, even still more preferably at least 10% higher, most preferably at least 20% higher than the fluid not comprising the additive. Of course the increase of the refractive index is i.a. dependant from the type of additive and the concentration of the additive in the fluid.

Examples of immersion fluids are water and various types of alkanes as well as in fluorinated and siloxane based fluids. The alkanes may comprise 6-10 carbon atoms. The pH of immersion fluid preferably is below 10, more preferably below 8, and even more preferably between 3-7.

Two types of additives may be added. Additives, which are soluble in the pure fluid, and additives, which are insoluble in the pure fluid and therefore must be dispersed as particles, preferably nano particles. As soluble additives, both organic compounds and liquids, and inorganic compounds, for example salts, may be used. In case of water as fluid, examples of organic compounds include: various types of sugars, alcohols such as for example cinnamyl alcohol and elthylene glycol, 2-picoline, phosphorus or sulphur containing compounds, such as for example salts of polyphosphoric acids, sodium polyphosphate, sodium hexametaphosphate, cesium hexametaphosphate, cesium polyphosphate ethoxy-(ethoxy-ethyl-phosphinothioylsulfanyl)-acetic acid ethyl ester, 1-fluoro-1-(2-hydroxy-phenoxy)-3-methyl-2,5-dihydro-1H-1λ5-phosphol-1-ol and water soluble functionalised silicon oil. Examples of inorganic compounds include: mercury monosulphide, mercury(I) bromide, marcasite, calcite, sodium chlorate, lead monoxide, pyrite, lead(II) sulfide, copper(II) oxide, lithium fluoride, tin(IV) sulphide, lithium niobate and lead(II) nitrate.

The soluble additives may further comprise compounds having the general formulae:
RAₙ,
where R is a hydrocarbon group with preferably 1-100 carbon atoms, more preferably 1-10 carbon atoms. The R group may be partly or fully fluorinated and may have a branched or a cyclic structure or a combination thereof. The groups A are acidic groups or corresponding salts of for example phosphonic, phosphinic, sulfonic and carboxylic acids. Preferably n is 1-10.

Preferably the immersion fluid comprises between 1 and 70 wt. % of the soluble additive, more preferably between 2 and 50 wt. %, still more preferably between 20 and 45 wt. % Preferably insoluble additives are used. Preferably as insoluble compounds nano particles are used in immersion fluids for example organic, inorganic or metallic nano particles. The average size of the particles is preferably 10 times, more preferable 20 times, still more preferably 30 times and even still more preferably 40 times smaller than the corresponding exposure wavelength, the wave length of the exposure light used in the method according to the invention. In this way the average size of the nano particles may be less than 100 nanometer (nm), preferably less than 50 nm, more preferably less than 30 nm, still more preferably less than 20 nm, most preferably less than 10 nm. This results in a high transparency of the immersion fluid, especially at the wave length of the exposure light. The particles may have a minimum size of 0.1 nm.

For measuring the dimensions of the nano-particles the particles are in a very dilute mixture applied on a surface in a thin layer, so that at a microscopic (for example FE-SEM (Field Emission Scanning Electron Microscopy) or AFM (atomic force microscopy)) photographic image of the layer, the single nano-particles are observable. Than from 100 nanoparticles, ad random selected, the dimensions are determined and the average value is taken. In case of particles having an aspect ratio above 1, like platelets, rods or worm-shaped nano-particles, as the size the distance from one end to the most remote other end is taken.

The volume percentage of the nano particles in the fluid is preferable at least 10%, more preferably at least 20%, still even more preferably at least 30%, even still more preferably at least 40%. Most preferably the volume percentage is at least 50%, as this results in a fluid having a high refractive index, a high transparency and low amount of scattering of the incident light. Preferably the volume percentage is below 80%, more preferably below 70%. Examples of inorganic and metallic nano particles include: Aluminium nitride, Aluminium oxide, Antimony pent oxide, Antimony tin oxide, Brass, Calcium carbonate, Calcium chloride, Calcium oxide, Carbon black, Cerium, Cerium oxide, Cobalt, Cobalt oxide, Copper oxide, Gold, Hastelloy, Hematite-(alpha, beta, amorphous, epsilon, and gamma), Indium tin oxide, Iron-cobalt alloy, Iron-nickel alloy, Iron oxide, Iron oxide, Iron sulphide, Lanthanum, Lead sulphide, Lithium manganese oxide, Lithium titanate, Lithium vanadium oxide, Luminescent, Magnesia, Magnesium, Magnesium oxide, Magnetite, Manganese oxide, Molybdenum, Molybdenum oxide, Montmorillonite clay, Nickel, Niobia, Niobium, Niobium oxide, Silicon carbide, Silicon dioxide preferably amorphous silicon dioxide, Silicon nitride, Silicon nitride, Yttrium oxide, Silicon nitride, Yttrium oxide, Silver, Specialty, Stainless steel, Talc, Tantalum, Tin, Tin oxide, Titania, Titanium, Titanium diboride, Titanium dioxide, Tungsten, Tungsten carbide-cobalt, Tungsten oxide, Vanadium oxide, Yttria, Yttrium, Yttrium oxide, Zinc, Zinc oxide, Zirconium, Zirconium oxide and Zirconium silicate. Best results are obtained by using particles of a material, which material is highly transparent for radiation at the exposure wave length, for example at a wave length of 248, 193 or 157 nm, for example the material having a transmission of at least 50%, as measured over a theoretical light path of 1 mm.

In a preferred embodiment nano particles comprising an Al³⁺-compound are used in the immersion fluid of the process according to the invention. This is because such an immersion fluid has not only a very high refractive index, but is also highly transparent. Good examples of such particles include Al₂O₃ preferably crystalline α-Al₂O₃ (Sapphire) and γ-Al₂O₃. Further suitable types of Al₂O₃ are mentioned in Z. Chemie. 25 Jahrgang, August 1985, Heft 8, p. 273-280. In this case good results are obtained if the immersion fluid comprises 25-65 vol. % of the nano particles comprising the Al³⁺-compound. Preferably an immersion fluid comprising 25-45 vol. %, more preferably 30-40 vol. % of the particles is used. Also good results are obtained by using nano particles of fused amorphous SiO₂, MgO, nanodiamond, MgAl₂O₄ or nano particles comprising a mixture of fused amorphous SiO₂ and Al₂O₃. Such immersion fluids not only have favourable optical properties, like a high refractive index and a high transparency, but is also well processable in the standard apparatus for producing microchips. For example the viscosity is low enough, so that the immersion fluid can be pumped easily.

It is known to the skilled person how to make nano particles and stable dispersions of the nano particles in immersion fluids.

For the preparation of nano particles both wet and solid state techniques may be used. Wet methods include sol-gel techniques, hydrothermal processing, synthesis in supercritical fluids, precipitation techniques and micro emulsion technology. Solid state techniques include gas phase methods like flame/plasma techniques and mechano-chemical processing. In particular good results are obtained with wet methods such as sol-gel techniques. The sol-gel reaction can be carried out in aqueous media in which case the particles are charged stabilised. The counter ions are chosen in such a way to ensure high optical transmission at corresponding wavelengths. Preferably phosphorous containing counter ions such as phosphoric acid are used. Alternatively the sol-gel reaction may be carried out in non-aqueous media for example alkanes like decane or cyclic alkanes like decaline. In this case, the nano-particles are stabilised by addition of suitable dispersing agents. In this way high concentration, so high refractive index, and low viscosity are obtained. To ensure low absorption at deep-UV wavelengths, preferably fluorinated dispersing agents are used. After the sol-gel synthesis at ambient pressures, the fluid containing nanoparticles may be heated under pressure to increase the density and also change the crystalline structure of particles. In this way, particles with superior optical properties such as high refractive index can be produced.

Also a combination of the flame hydrolysis and a wet method may be used in which the particles, produced at elevated temperatures, are directly deposited in the fluids such as water or alkanes such as for example decane or cyclic alkanes such as for example decaline. This method has the advantage that aggregation and agglomeration of highly pure nano-particles is prevented.

It is also possible to use an immersion fluid in the process according to the invention, comprising a mixture of one or more soluble and one or more insoluble additives.

In a further preferred embodiment a fluid is used comprising transparent particles having a refractive index higher than the refractive index of the pure fluid and the additive in an amount, such that the refractive index of the fluid comprising the additive is equal to the refractive index of the transparent particles. Normally because of their size the transparent particles would scatter at least part of the exposure light. However, in this way because the refractive index of the transparent particles is equal to the refractive index of the surrounding fluid, the particles will not scatter any of the exposure light.

The transparent particles for example have an average size of larger than 0.4 microns, preferably of 0.5-1000 microns. More preferably the transparent particles have an average size of 1-100 microns. Even more preferably 90 wt. % of the transparent particles have a size between 1 and 10 microns, most preferably between 4 and 10 microns.

Preferably the particles have a broad weight distribution and a spherical shape. In this way a high loading of the fluid with the transparent particles is possible, while the fluid still can be handled very well in the process for producing the chips, the fluid still having a very high transparency.

The weight percentage of transparent particles in the immersion fluid containing the additive in an amount, such that the refractive index of the fluid comprising the additive is equal to the refractive index of the transparent particles, is preferably higher than 20%, more preferably higher than 40%, and even more preferably higher than 60%.

The transparent particles may consist of a material having a transmission of least 40% (as measured over a theoretical light path of 1 mm). Preferably this transmisson is at least 60%, more preferably at least 80%, still more preferably at least 90%, most preferably at least 95%. Examples of suitable transparent particles are particles of transparent crystals, for example SiO₂, Al₂O₃, MgO and HfO₂. Preferably amorphous SiO₂ particles, sapphire particles or MgO particles are used.

More preferably particles of fused amorphous SiO₂ are used, having a purity of at least 99 wt. %, more preferably at least 99.5 wt. %, still more preferably at least 99.9 wt. %. In this way a fluid having still further improved transparency is obtained

Examples of particles of fused amorphous SiO₂ suitable for use in the immersion fluid are of the Lithosil™ series preferably Lithosil™Q0/1-E193 and Lithosil™Q0/1-E248 (produced by Schott Lithotec), and fused amorphous SiO₂ of the HPFS series with the Corning code 7980 (produced by Corning) as used for the production of lenses for apparatus for the production of chips. Such fused amorphous SiO₂ is very pure and therefore may have a transparency of more than 99%. A method of producing such particles is by flame hydrolysis, a method known to the person skilled in the art.

In order to increase the refractive index of the particles of fused amorphous SiO₂ it possible to dope the particles with small amounts of suitable doping elements, for example Germanium.

In the fluid comprising the transparent particles, as the additive one or more of the above-referred soluble or insoluble additives may be used. Preferably an additive that is soluble in the fluid is used, preferably cesium sulphate, cesium hexametaphosphate or sodium hexametaphosphate.

In a further preferred embodiment a fluid is used comprising transparent particles which are functionalised on their surface in such a manner that they become dispersible in the immersion fluid. This is for example possible by grafting the particles with a surfactant, preferably a polymeric surfactant. It is also possible for purpose of dispersing the transparent particles to add a surfactant to the immersion fluid comprising the transparent particles.

In a preferred embodiment the method according to the invention comprises the steps of:

a) measuring the refractive index of the immersion fluid directly or indirectly,

b) adjusting the refractive index of the immersion fluid at a predetermined value by adding extra, pure fluid or adding extra additive to the immersion fluid.

In this way fluctuations in the refractive index due to variations in temperature and concentration of the additive are compensated for.

The refractive index may be measured as such directly. It is also possible to measure one or more other parameters, being a measure for the refractive index. In case the immersion fluid comprises the transparent particles and the additive in an amount, such that the refractive index of the fluid comprising the additive is equal to the refractive index of the transparent particles, it is possible to determine the light scattering of the transparent particles and to add pure fluid or additive to reduce the light scattering. The addition of extra pure fluid may suitably be carried out by mixing extra pure fluid with the immersion fluid. The addition of extra additive may suitably be carried out by mixing a concentrated solution or dispersion of the additive in the pure fluid with the immersion fluid.

A still further preferred embodiment of the method according to the invention comprises the steps of

a) transporting the immersion fluid after being used in the production of a microchip to a cleaning unit,

b) cleaning the immersion fluid

c) recycling the cleaned immersion fluid into the process for producing the chips.

Due to the extraction of components from the photoresist layer on top of the wafer, possible chemical changes in the fluid components during the exposure step and further reasons, the immersion fluid will tend to be contaminated. This means that after a certain period of using the fluid in the process of the present invention, the fluid has to be refreshed. However this increases fluid consumption and negatively influences the process economics. Surprisingly it is possible to clean the fluid and recycle the cleaned fluid into the process of the present invention.

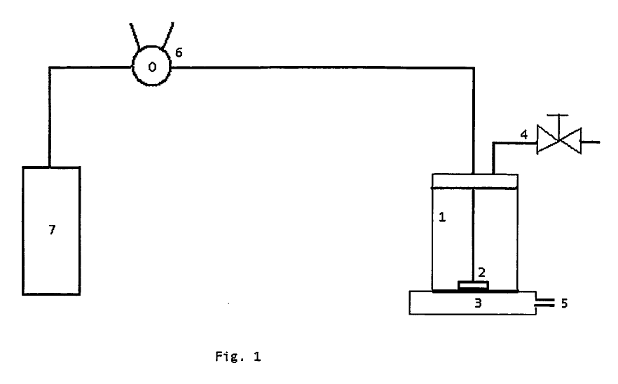

Cleaning of the fluid is suitably carried out by cross flow filtration or dead end flow filtration using for example membranes for microfiltration, ultrafiltration, nanofiltration or reverse osmoses. Good results are obtained if a stirred pressure cell is used. An example of a stirred pressure cell is given in FIG. 1.

In FIG. 1 a stirred pressure cell is shown comprising a cell housing 1, having a stirrer 2, and an inlet for the used immersion fluid. Between the cell housing 1 and chamber 5 a membrane 3 is mounted. From gas cylinder 7, via pressured regulater 6 a pressure is applied on top of the fluid in cell housing 1. Due to this pressure fluid comprising contaminants is transported through the membrane in chamber 5 and transported further. In cell housing 1 a concentrated fluid composition comprising particles for example nano particles and/or transparent particles remains. Thereafter the refractive index of the concentrated fluid is adjusted to its original value again by adding pure fluid and if appropriate soluble additive.

Preferably the immersion fluid has a transmission at one or more wavelength out of the group of 248, 193 and 157 nm of at least 10% through a path-length of 1 mm, more preferably at least 20%, still more preferably at least 30%, even still more preferably at least 40%, most preferably at least 50%.

The invention also relates to an apparatus for immersion lithography for the production of microchips, comprising the immersion fluid.

### EXAMPLES I-10

Dispersions of nano particles of α-Al₂O₃, γ-Al₂O₃, MgO, MgAl2O₄ are produced by the sol-gel method. Using this method the corresponding precursors are first dissolved in water or in decaline and a hydrolysis reaction is initiated. After that a hydro-thermal treatment is carried out followed by a peptisation step. Immersion fluids are finally produced by diluting the so obtained dispersions with water, respectively decalin.

Nanoparticles of diamond are first produced by solid-sate method and then dispersed in water and decaline to obtain the immersion fluids. The refractive indices are measured at 193 nm and 248 nm using ellipsometer VUV-VASE produced by J.A. Woollam Co., Inc (US). The results are shown in table 1 for different volume percentages of nano particles.

TABLE 1
Refractive indices (RI) of dispersions of various
nanoparticles measured at 193 nm and 248 nm.

| | | | RI @ 193 | RI @ 248 |
|---|---|---|---|---|
| | | Average | nm in | nm in |
| | | particle | water | water |
| Additive | Volume (%) | size (nm) | (decane) | (decaline) |
| α-Al₂O₃ | 10 | 5 | 1.49 (1.58) | — |
| α-Al₂O₃ | 40 | 5 | 1.63 (1.70) | — |
| Y—Al₂O₃ | 10 | 6 | 1.48 (1.58) | — |
| Y—Al₂O₃ | 40 | 6 | 1.62 (1.70) | — |
| MgO | 10 | 7 | 1.50 (1.59) | — |
| MgO | 40 | 7 | 1.66 (1.72) | — |
| MgAl₂O₄ | 10 | 5 | 1.48 (1.57) | — |
| MgAl₂O₄ | 40 | 5 | 1.58 (1.64) | — |
| Nano- | 10 | 8 | — | 1.46 (1.52) |
| diamond | | | | |
| Nano- | 40 | 8 | — | 1.64 (1.70) |
| diamond | | | | |

In all cases an increase in the refractive index are obtained. Nano diamond particles especially show good results at a wave length of 248 nm.

### EXAMPLE 11-14

Solution of different water soluble additives are prepared. The refractive indices are measured at 193 nm and 248 nm using ellipsometer VUV-VASE produced by J.A. Woollam Co., Inc (US). The data are shown in table 2.

TABLE 2
Refractive indices (RI) of solutions of various
additives measured at 193 nm and 248 nm.

| | | RI @ 193 | RI @ 248 |
|---|---|---|---|
| | | nm in | nm in |
| Additive | Wt (%) | water | water |
| Cs₂SO₄ | 40 | 1.48 | 1.42 |
| H₃PO₄ | 20 | 1.45 | 1.40 |
| H₃PO₄ | 40 | 1.48 | 1.42 |
| H₃PO₄ | 85 | 1.54 | 1.49 |

The immersion fluids are used in an apparatus for producing microchips, based on immersion technology at wave length of 193 nm.

1. Method for producing microchips by using immersion lithography, characterised in that the immersion fluid comprises an additive so that the refractive index of the immersion fluid is higher than the refractive index of the fluid not comprising the additive.

2. Method for producing microchips according to claim 1, characterised in that the refractive index of the immersion fluid is at least 1% higher.

3. Method according to claim 1 or 2, characterised in that the additive is soluble in the immersion fluid.

4. Method according to claim 3, characterized in that the immersion fluid comprises 1-70 wt. % of the soluble additive.

5. Method according to claim 1 or 2, characterised in that the additive is insoluble in the immersion fluid.

6. Method according to claim 5, characterised in that the immersion fluid comprises as the insoluble additive nano particles.

7. Method according to claim 6, characterised in that the nano particles have an average size that is 10 times smaller than the wavelength of the exposure light.

8. Method according to claim 6, characterised in that the nano particles have an average size of less than 100 nm.

9. Method according to claim 6, characterised in that the fluid comprises at least 10 volume % of the nano particles.

10. Method according to claim 6, characterised in that the particles are used of a material that has a transmission of at least 50%, as measured over a theoretical light path of 1 mm.

11. Method according to claim 10, characterised in that nano particles comprising an Al 3+-compound are used.

12. Method according to claim 10, characterised that nano particles of fused amorphous SiO₂, MgO, nanodiamond, MgAl₂O₄ nano particles comprising a mixture of fused amorphous SiO₂ and Al₂O₃ are used.

13. Method according to claim 1, characterized in that the fluid comprises transparent particles having a refractive index higher than the refractive index of the pure fluid and the additive in an amount, such that the refractive index of the fluid comprising the additive is equal to the refractive index of the transparent particles.

14. Method according to claim 13, characterised in that the transparent particles have an average size of 1 1000 microns.

15. Method according to claim 13, characterised in that the transparent particles are of transparent crystals of SiO₂, Al₂O₃, MgO or HfO₂.

16. Method according to claim 1 characterised in that the method comprises the steps of
a) transporting the immersion fluid after being used in the production of a microchip to a cleaning unit,
b) cleaning the immersion fluid
c) recycling the cleaned immersion fluid into the process for producing the chips.

17. Apparatus for producing microchips, based on the technology of immersion lithography, characterised in that the apparatus comprises the immersion fluid as used in the process of claim 1.
